(19) United States
(12) Patent Application Publication
(10) Pub. No.: US 2008/0182392 A1
(43) Pub. Date: Jul. 31, 2008

(54) Method for fabricating polysilicon layer with large and uniform grains

(75) Inventors: Guan-Hua Yeh, Miao-Li (TW); Hong-Gi Wu, Miao-Li (TW); Jung-Lung Huang, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 12/011,804

(22) Filed: Jan. 29, 2008

(30) Foreign Application Priority Data
Jan. 29, 2007 (TW) 96103220

(51) Int. Cl. H01L 21/36

(52) U.S. Cl. 438/486; 257/E21.461

(57) ABSTRACT

An exemplary method for fabricating a polysilicon layer (208) includes the following steps. A substrate (200) is provided, and a first amorphous silicon layer (203) is formed over the substrate. Portions of the first amorphous silicon layer are removed through a photolithograph process to form a plurality of crystallization seeds (205). A second amorphous silicon layer (206) is formed over the substrate and the crystallization seeds. A laser annealing process is conducted to crystallize the amorphous silicon layer into a polysilicon layer.

### FIELD OF THE INVENTION

The present invention relates to methods for fabricating polysilicon layers, and particularly to a method for fabricating a polysilicon layer with large and uniform grains.

### BACKGROUND

At present, liquid crystal displays (LCDs) are the most common type of displays used in products such as notebook computers, game centers, and the like.

The principal driving devices for an LCD are thin film transistors (TFTs). Because the amorphous silicon layer in amorphous silicon TFTs can be made at a relatively low temperature (between 200° C. and 300° C.), amorphous silicon TFTs are frequently used in LCDs. However, the electron mobility of amorphous silicon is lower than 1 cm²/V.S. (one square centimeter per volt second). Hence, amorphous silicon TFTs cannot provide the speeds required of an LCD in certain high-speed devices. On the other hand, the polycrystalline silicon (or polysilicon) TFT has electron mobility as high as 200 cm²/V.S. Therefore polysilicon TFTs are more suitable for high-speed operations. However, the process of transforming an amorphous silicon layer into a polysilicon layer often requires an annealing temperature in excess of 600° C. Under that temperature, the glass substrate supporting the TFTs is liable to be distorted. Thus, a number of methods for fabricating a polysilicon layer at a reduced temperature have been developed. Among such methods, the excimer laser annealing (ELA) method is the most prominent. Because the temperature of the ELA method is under 500° C., the polysilicon layers fabricated using such low temperature process are often called low temperature polysilicon layers.

FIGS. 9-12 are schematic, side cross-sectional views of part of a treated substrate, showing sequential stages of fabricating a polysilicon layer by a conventional ELA process.

In step 1, referring to FIG. 9, a substrate 100 is provided. The substrate 100 can be made of glass. Then a buffer layer 101 is formed on the substrate 100. The buffer layer 101 can be a silicon oxide layer.

In step 2, referring to FIG. 10, an amorphous silicon layer 103 is formed on the buffer layer 101.

In step 3, referring to FIG. 11, an ELA process is conducted. The amount of radiation energy incident on the amorphous silicon layer 103 provided by the excimer laser is carefully controlled, such that the entire amorphous silicon layer 103 is almost completely melted. Hence, only a few particles of the original amorphous silicon layer 103 remain on top of the buffer layer 101. The particles serve as crystallization seeds. Thereafter, the melted silicon starts to crystallize from the crystallization seeds, eventually forming a polysilicon layer 104. The polysilicon layer 104 contains a plurality of non-uniformly distributed crystal grains 106, grain boundaries 107, and protrusions 108 formed at the corresponding grains boundaries 107.

In step 4, referring to FIG. 12, the protrusions 108 are removed by a plasma etching process to planarize the polysilicon layer 104.

In the above-described ELA process, the crystallization seeds are randomly formed at various positions on the buffer layer 101. Therefore, the fabricated polysilicon layer 104 has a plurality of non-uniform polysilicon grains grown from the crystallization seeds. Moreover, it is hard to precisely control the radiation energy applied to the amorphous silicon layer 103. If the radiation energy provided to the amorphous silicon layer 103 exceeds a super lateral growth (SLG) point, a density distribution of the crystallization seeds may drop to a very low value within a transient interval. The sudden loss of crystallization seeds may lead to the production of a lot of small and highly non-uniform grains. The polysilicon layer 104 having small and non-uniform grains has relatively low electron mobility.

Accordingly, what is needed is a method for fabricating a polysilicon layer that can overcome the above-described deficiencies.

### SUMMARY

In one preferred embodiment, a method for fabricating a polysilicon layer includes the following steps: providing a substrate, and forming a first amorphous silicon layer over the substrate; removing portions of the first amorphous silicon layer to form a plurality of crystallization seeds through a photolithograph process; forming a second amorphous silicon layer over the substrate, the second amorphous silicon layer covering the crystallization seeds; and conducting a laser annealing process to crystallize the amorphous silicon layer into a polysilicon layer.

In an alternative embodiment, a method for fabricating a polysilicon layer includes the following steps: providing a substrate, and forming a first amorphous silicon layer on the substrate; etching the first amorphous silicon layer to form a plurality of silicon particles; forming a second amorphous silicon layer over the substrate, the second amorphous silicon layer covering the silicon particles; and melting the second amorphous silicon layer and crystallizing the melted silicon into a polysilicon layer with the silicon particles as crystallization seeds.

Other novel features and advantages will become more apparent from the following detailed description when taken in conjunction with the accompanying drawings.

### BRIEF DESCRIPTION OF THE DRAWINGS

FIG. 1 is a flowchart summarizing a method for fabricating a polysilicon layer according a preferred embodiment of the present invention.

FIGS. 2 to 8 are schematic, side cross-sectional views of part of a treated substrate, showing sequential stages of the preferred method for fabricating a polysilicon layer.

FIG. 9 to 12 are schematic, side cross-sectional views of part of a treated substrate, showing sequential stages of fabricating a polysilicon layer by a conventional ELA process.

### DETAILED DESCRIPTION OF PREFERRED EMBODIMENTS

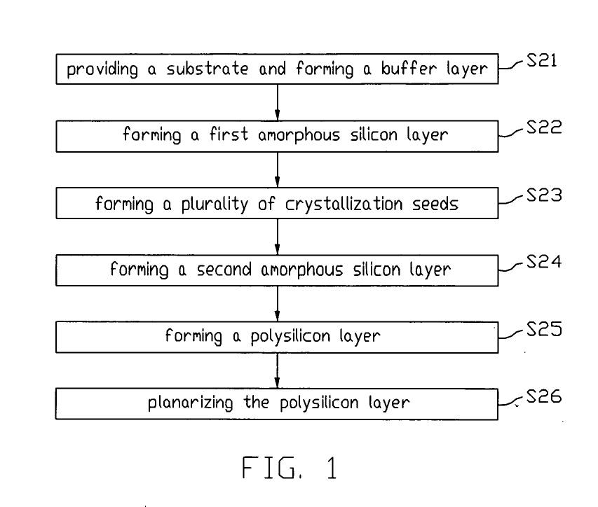

FIG. 1 is a flowchart summarizing a method for fabricating a polysilicon layer according a preferred embodiment of the present invention. The method includes: step S21, providing a substrate and forming a buffer layer; step S22, forming a first amorphous silicon layer; step 23, forming a plurality of crystallization seeds; step 24, forming a second amorphous silicon layer; step 25, forming a polysilicon layer; and step 26, planarizing the polysilicon layer.

In step S21, referring to FIG. 2, a substrate 200 is provided. The substrate 200 can be a glass substrate. Then a buffer layer 201 is formed on the substrate 200. The buffer layer 201 is used for preventing impurities in the substrate 200 from diffusing into the silicon layers formed in subsequent steps. Thereby, the quality of a polysilicon layer eventually produced can be optimized. The buffer layer 201 can be a silicon oxide layer, a silicon nitride layer, or a multilayer structure having at least one silicon nitride layer and at least one silicon oxide layer.

In step S22, referring to FIG. 3, a first amorphous silicon layer 203 is formed on the buffer layer 201. The first amorphous silicon layer 203 may have a thickness of 50-100 nanometers (nm). The first amorphous silicon layer 203 can be made using a method such as vacuum evaporation, sputtering, plasma enhanced chemical vapor phase deposition (PECVD), low pressure chemical vapor phase deposition (LPCVD), and the like.

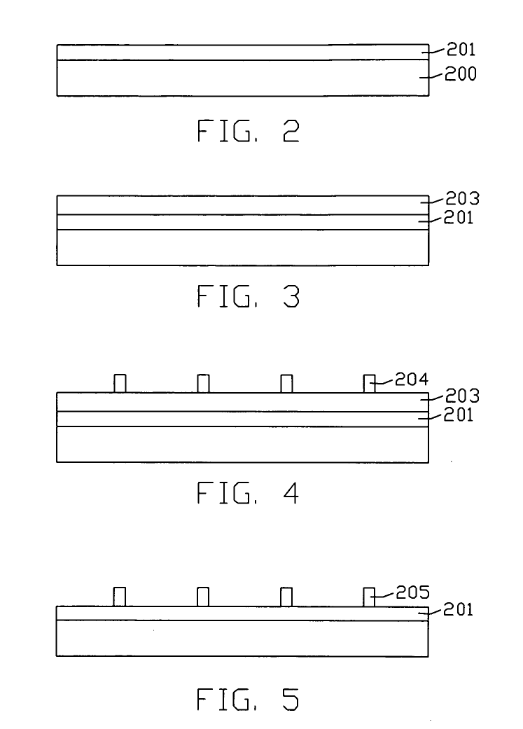

In step S23, referring to FIG. 4, a photo-resist layer (not shown) is formed on the first amorphous silicon layer 203. The photo-resist layer is then exposed and developed, thereby forming a photo-resist pattern 204. The photo-resist pattern 204 covers predetermined points of the amorphous silicon layer 203 in a uniform pattern.

Referring also to FIG. 5, using the photo-resist pattern 204 as a mask, a portion of the first amorphous silicon layer 203 that is not covered by the photo-resist pattern 204 is etched away by means of a dry etching method. Then the photo-resist pattern 204 is removed by an acetone solution. Thereby, the remaining uniformly spaced-apart points of the first amorphous silicon layer 203 serve as crystallization seeds 205. A distance between each two adjacent crystallization seeds 205 is in a range of 0.5-3 micrometers (pan), and preferably 2 μm. An etchant of the dry etching method is a mixture of sulfur hexafluoride (SF₆) and carbon tetrafluoride (CF₄).

The etching method can also be a wet etching method. An etchant of the wet etching method is an aqueous solution of nitric acid (HNO₃) and ammonium fluoride (NH₄F). A preferred volume ratio of HNO₃:NH₄F:H₂O can for example be 64:3:33.

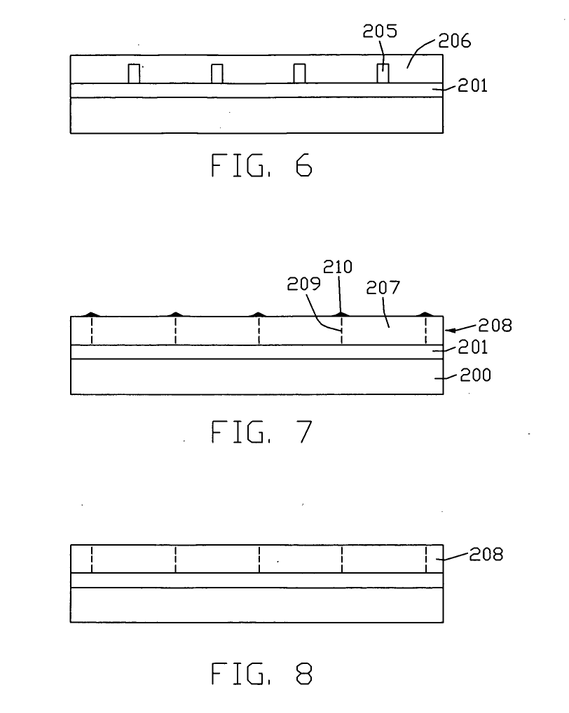

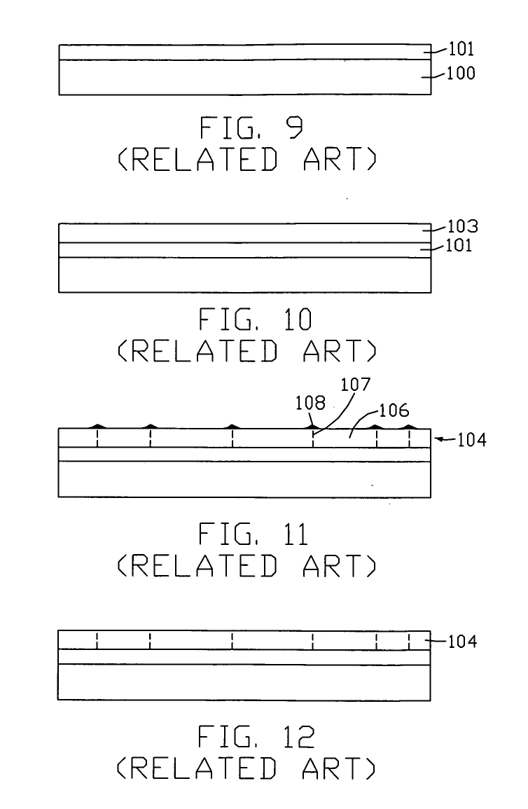

In step 24, referring FIG. 6, a second amorphous silicon layer 206 is formed on the buffer layer 201. The second amorphous silicon layer 206 completely covers the crystallization seeds 205. The second amorphous silicon layer 206 can be made using a method such as vacuum evaporation, sputtering, plasma enhanced chemical vapor phase deposition (PECVD), low pressure chemical vapor phase deposition (LPCVD), and the like. Thereafter, superfluous hydrogen in the second amorphous silicon layer 206 is removed, in order to avoid hydrogen explosion in a subsequent ELA process.

In step 25, referring to FIG. 7, an ELA process is conduced to change the second amorphous silicon layer 206 into a polysilicon layer. During the ELA process, an excimer laser beam irradiates the second amorphous silicon layer 206. Then the second amorphous silicon layer 206 is completely melted. Because the crystallization seeds 205 are made from the first amorphous silicon layer 203 and are under the second amorphous silicon layer 206, the crystallization seeds 205 have a lower temperature than that of the second amorphous silicon layer 206. Therefore, the crystallization seeds 205 are not melted. Thereafter, the temperature of the melted silicon decreases. The melted silicon starts crystallizing from the crystallization seeds 205 to form a plurality of crystal grains 207. The crystal grains 207 grow and meet each other at corresponding boundaries 209. The crystal grains 207 press on each other, thereby forming a plurality of protrusions 210. Thus, a polysilicon layer 208 is formed. Because the crystallization seeds 205 are uniformly spread on the buffer layer 201 a predetermined distance apart from one another, the crystal grains 207 grow to have large and uniform sizes.

In the above-described step of forming a polysilicon layer from the second amorphous silicon layer 206, the thermal energy of the excimer laser is carefully controlled, in order that the buffer layer 201 and the substrate 200 have high and homogenous thermal distribution. This prolongs the growing time of the crystal grains 207 and facilitates forming of a polysilicon layer 208 having large and uniform grains.

In step S26, referring to FIG. 8, the protrusions 210 of the polysilicon layer 208 are removed so that the polysilicon layer 208 becomes planar. The planarizing method can for example be a plasma etching method, a chemical mechanical polishing method, a chemical wet etching method, or an excimer laser annealing method.

In the above-described preferred method, the crystallization seeds 205 are formed by the first amorphous silicon layer 203 through a photolithographic process. The positions of the crystallization seeds 205 and a distribution density of the crystallization seeds 205 are controllable. This ensures that the crystallization seeds 205 can be formed exactly where required. Thus the crystal grains 207 growing from the crystallization seeds 203 are uniformly distributed, the crystal grains 207 have larger crystal sizes, and there are fewer grain boundaries 209. Accordingly, the polysilicon layer 208 having large and uniform grains is formed. The polysilicon layer 208 fabricated according to the above-described method has high electron mobility. The high electron mobility improves the quality of TFTs subsequently formed from the polysilicon layer.

It is to be further understood that even though numerous characteristics and advantages of various embodiments have been set forth in the foregoing description, together with details of the related structures and functions of the embodiments, the disclosure is illustrative only, and changes may be made in detail to the full extent indicated by the broad general meaning of the terms in which the appended claims are expressed.

What is claimed is:

1. A method for fabricating a polysilicon layer, the method comprising:
providing a substrate, and forming a first amorphous silicon layer over the substrate;
removing portions of the first amorphous silicon layer to form a plurality of crystallization seeds through a photolithographic process;
forming a second amorphous silicon layer over the substrate, the second amorphous silicon layer covering the crystallization seeds; and
conducting a laser annealing process to crystallize the amorphous silicon layer into a polysilicon layer.

2. The method for fabricating a polysilicon layer as claimed in claim 1, wherein the portions of the first amorphous silicon layer are removed via a dry etching process.

3. The method for fabricating a polysilicon layer as claimed in claim 2, wherein an etchant of the dry etching process is a mixture of sulfur hexafluoride and carbon tetrafluoride.

4. The method for fabricating a polysilicon layer as claimed in claim 1, wherein the portions of the first amorphous silicon layer are removed via a wet etching process.

5. The method for fabricating a polysilicon layer as claimed in claim 4, wherein an etchant of the wet etching process is an aqueous solution of nitric acid and ammonium fluoride.

6. The method for fabricating a polysilicon layer as claimed in claim 1, wherein each two adjacent crystallization seeds are spaced apart a distance in the range from 0.5 micrometers-to 3 micrometers.

7. The method for fabricating a polysilicon layer as claimed in claim 6, wherein each two adjacent crystallization seeds are spaced apart a distance of 2 micrometers.

8. The method for fabricating a polysilicon layer as claimed in claim 1, wherein the substrate is a glass substrate.

9. The method for fabricating a polysilicon layer as claimed in claim 1, wherein the first and second amorphous silicon layers are each formed by a process selected from the group consisting of vacuum evaporation, sputtering, low pressure chemical vapor deposition, and plasma enhanced chemical vapor deposition.

10. The method for fabricating a polysilicon layer as claimed in claim 1, further comprising, before forming the first amorphous silicon layer, forming a buffer layer on the substrate, with the first amorphous silicon layer being subsequently formed on the buffer layer.

11. The method for fabricating a polysilicon layer as claimed in claim 10, wherein the buffer layer is one of a silicon oxide layer and a silicon nitride layer.

12. The method for fabricating a polysilicon layer as claimed in claim 10, wherein the buffer layer is a multilayer having at least one silicon nitride layer and at least one silicon oxide layer.

13. The method for fabricating a polysilicon layer as claimed in claim 1, further comprising planarizing the polysilicon layer.

14. The method for fabricating a polysilicon layer as claimed in claim 13, wherein the polysilicon layer is planarized by a process selected from the group consisting of plasma etching, chemical mechanical polishing, chemical wet etching, and excimer laser annealing.

15. A method for fabricating a polysilicon layer, the method comprising:
providing a substrate, and forming a first amorphous silicon layer over the substrate;
etching the first amorphous silicon layer to form a plurality of silicon particles;
forming a second amorphous silicon layer over the substrate, the second amorphous silicon layer covering the silicon particles; and
melting the second amorphous silicon layer and crystallizing the melted silicon into a polysilicon layer, wherein the silicon particles act as crystallization seeds.

16. The method for fabricating a polysilicon layer as claimed in claim 15, wherein the silicon particles are formed through a photolithographic process.

17. The method for fabricating a polysilicon layer as claimed in claim 15, wherein the second amorphous silicon layer is crystallized through an excimer laser annealing process.

18. The method for fabricating a polysilicon layer as claimed in claim 15, further comprising, before forming the first amorphous silicon layer, forming a buffer layer on the substrate, with the first amorphous silicon layer being subsequently formed on the buffer layer.

19. The method for fabricating a polysilicon layer as claimed in claim 15, further comprising planarizing the polysilicon layer.
